(19) United States
(12) Patent Application Publication
(10) Pub. No.: US 2013/0301396 A1
(43) Pub. Date: Nov. 14, 2013

(54) HOUSING FOR VIBRATION GENERATING APPARATUS AND VIBRATION GENERATING APPARATUS INCLUDING THE SAME

(71) Applicant: Jin Hoon KIM, Suwon (KR)

(72) Inventor: Jin Hoon KIM, Suwon (KR)

(73) Assignee: SAMSUNG ELECTRO-MECHANICS CO., LTD.

(21) Appl. No.: 13/600,921

(22) Filed: Aug. 31, 2012

(30) Foreign Application Priority Data
May 10, 2012 (KR) 10-2012-0049603

(51) Int. Cl. B06B 1/04; H05K 5/02

(52) U.S. Cl. 367/189; 312/223.1

(57) ABSTRACT

There is provided a housing for a vibration generating apparatus, the housing including: a bracket including a protrusion part protruding from an edge thereof; and a case coupled to the bracket and having an insertion hole into which the protrusion part is inserted when the case is coupled to the bracket.

### CROSS-REFERENCE TO RELATED APPLICATIONS

This application claims the priority of Korean Patent Application No. 10-2012-0049603 filed on May 10, 2012, in the Korean Intellectual Property Office, the disclosure of which is incorporated herein by reference.

### BACKGROUND OF THE INVENTION

1. Field of the Invention

The present invention relates to a housing for a vibration generating apparatus and a vibration generating apparatus including the same.

2. Description of the Related Art

Recently, the availability of personal portable communications terminals having large liquid crystal display (LCD) screens, provided for user convenience, has rapidly increased. Accordingly, a touch screen interface is adopted, and a vibration generating apparatus for generating vibrations at the time of a touch is used.

The vibration generating apparatus, a device for converting electrical energy into mechanical vibrations by using a principle of electromagnetic force, is mounted in the personal portable terminal, and is used to notify a user of a mute incoming call.

Of late, a linear type vibrator is commonly used, in order to overcome disadvantages of a motor type vibration generating apparatus in terms of lifespan and response speed and implement a vibration function in the touch screen.

The linear type vibrator does not use a principle of a rotational motor, but uses a principle of generating vibrations by producing resonance in the case that electromagnetic force obtained through a spring installed in the linear type vibrator and a mass body hung from the spring is periodically produced in accordance with a resonance frequency.

To this end, the linear type vibrator includes a magnet and a coil in order to generate vibrations through electromagnetic interaction therebetween.

Further, the magnet and the coil are disposed in a housing including a case and a bracket.

Meanwhile, the case has a cylindrical shape having one end opened and the other end closed, and the bracket has a disk shape. Further, the bracket is coupled to the open side of the case so that the open side of the case is closed.

However, in the case that external force is applied after the case and the bracket are coupled to each other, the bracket may be problematically deformed since the bracket and the case have a small contact area. That is, the bracket is not stably supported by the case, which problematically deforms the bracket in the case of an external shock.

Due to this deformation of the bracket, foreign objects may be introduced into an internal space formed by the bracket and the case, or the bracket and the vibrator may come into contact with each other when the linear type vibrator vibrates, causing problematic noise.

### RELATED ART DOCUMENT

### (Patent Publication 1) Korean Patent No. 0984046

### SUMMARY OF THE INVENTION

An aspect of the present invention provides a housing for a vibration generating apparatus capable of inhibiting a deformation thereof even in the case that external force is applied thereto, and a vibration generating apparatus including the housing.

According to an aspect of the present invention, there is provided a housing for a vibration generating apparatus including: a bracket including a protrusion part protruding from an edge thereof; and a case coupled to the bracket and having an insertion hole into which the protrusion part is inserted when the case is coupled to the bracket.

The case may include an extension part, thinner than a lower portion thereof, such that the edge of the bracket may be seated when the case is coupled to the bracket.

An upper portion of the extension part may be bent to thereby press a top edge of the bracket when the case is coupled to the bracket, and the insertion hole may be formed below the extension part.

The bracket may include a step part in the edge thereof supported by a seating surface of the case when the case is coupled to the bracket, and the protrusion part may extend from the step part.

The protrusion part may have an inclination surface formed in a lower portion thereof in order to facilitate the insertion of the protrusion part into the insertion hole.

The protrusion part may protrude from the edge of the bracket by a distance less than a thickness of the extension part in a radial direction.

The bracket and the case may have circular cross-sections, and the protrusion part and the insertion hole may be provided in plural, the plural protrusion parts and insertion holes respectively being spaced apart from each other in a circumferential direction.

According to another aspect of the present invention, there is provided a vibration generating apparatus including: a housing including a bracket having a protrusion part protruding from an edge thereof, and a case coupled to the bracket and having an insertion hole into which the protrusion part is inserted when the case is coupled to the bracket; a magnet installed in an internal space formed by the bracket and the case; and a vibrator vibrated through electromagnetic interaction with the magnet.

The case may include an extension part thinner than a lower portion thereof, such that the edge of the bracket may be seated when the case is coupled to the bracket, and the insertion hole may be formed below the extension part.

An upper portion of the extension part may be bent to thereby press a top edge of the bracket when the case is coupled to the bracket, the bracket may include a step part in the edge thereof supported by a seating surface of the case when the case is coupled to the bracket, and the protrusion part may extend from the step part.

The protrusion part may have an inclination surface formed in a lower portion thereof in order to facilitate the insertion of the protrusion part into the insertion hole, and the protrusion part may protrude from the edge of the bracket by a distance less than a thickness of the extension part in a radial direction.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view of a vibration generating apparatus according to an embodiment of the present invention;

FIG. 2 is an exploded perspective view of a vibration generating apparatus according to an embodiment of the present invention;

FIG. 3 is a perspective view of a housing for a vibration generating apparatus according to an embodiment of the present invention;

FIG. 4 is an exploded perspective view of a housing for a vibration generating apparatus before being assembled according to an embodiment of the present invention;

FIG. 5 is a cross-sectional view of the housing taken along line A-A′ of FIG. 3;

FIG. 6 is a cross-sectional view of the housing taken along line B-B′ of FIG. 3;

FIG. 7 is a schematic perspective view of a housing for a vibration generating apparatus according to another embodiment of the present invention;

FIG. 8 is a cross-sectional view of the housing taken along line C-C′ of FIG. 7; and

FIG. 9 is a cross-sectional view of the housing taken along line D-D′ of FIG. 7.

### DETAILED DESCRIPTION OF THE EMBODIMENTS

Embodiments of the present invention will now be described in detail with reference to the accompanying drawings. However, it should be noted that the spirit of the present invention is not limited to the embodiments set forth herein and those skilled in the art and understanding the present invention could easily accomplish retrogressive inventions or other embodiments included in the spirit of the present invention by the addition, modification, and removal of components within the same spirit, but those are to be construed as being included in the spirit of the present invention.

Further, when it is determined that the detailed description of the known art related to the present invention may obscure the gist of the present invention, a detailed description thereof will be omitted.

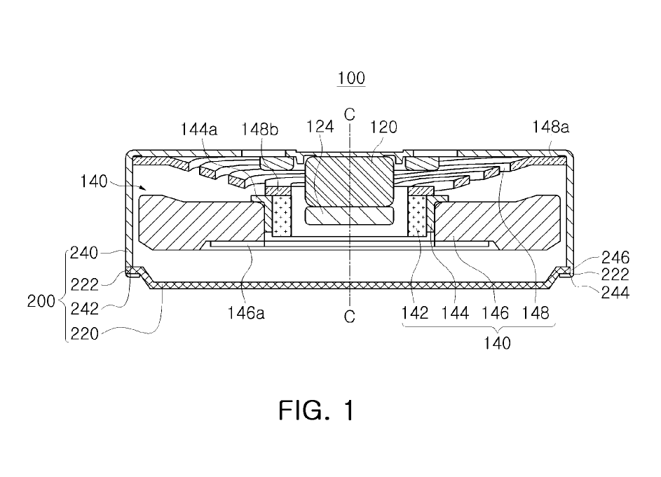

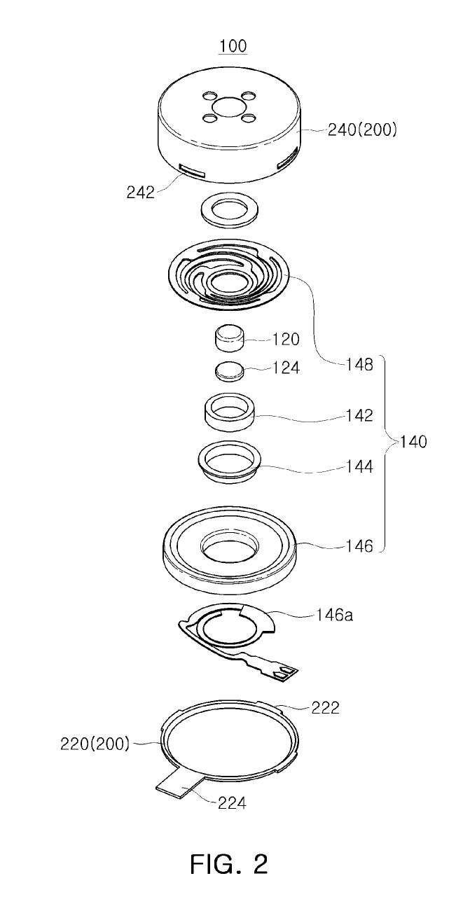

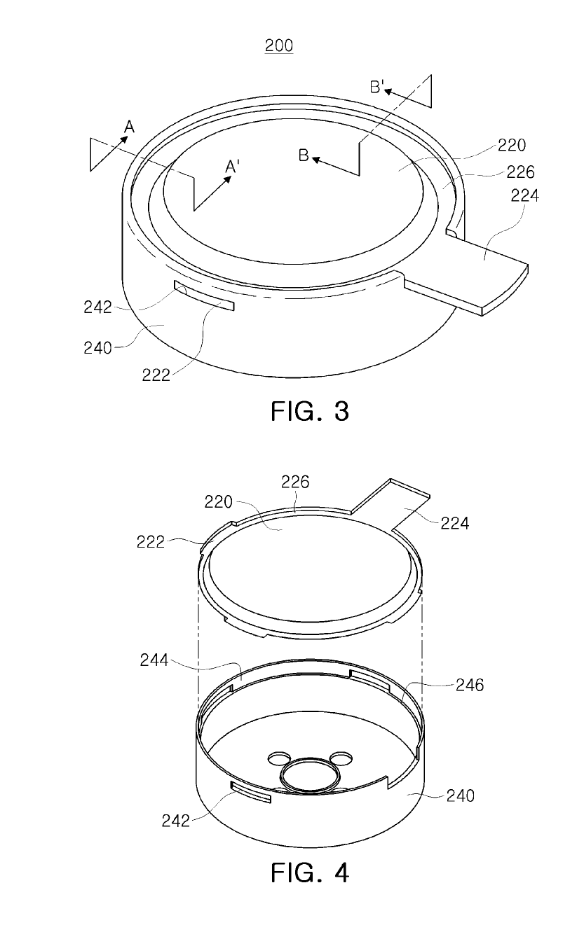

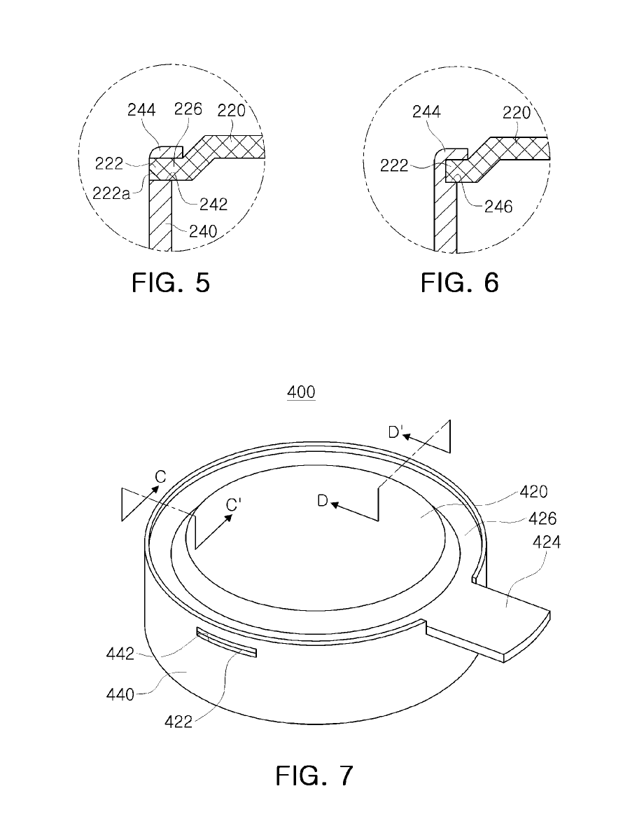

FIG. 1 is a schematic cross-sectional view of a vibration generating apparatus according to an embodiment of the present invention. FIG. 2 is an exploded perspective view of a vibration generating apparatus according to an embodiment of the present invention. FIG. 3 is a perspective view of a housing for a vibration generating apparatus according to an embodiment of the present invention. FIG. 4 is an exploded perspective view of a housing for a vibration generating apparatus before being assembled according to an embodiment of the present invention. FIG. 5 is a cross-sectional view of the housing taken along line A-A′ of FIG. 3. FIG. 6 is a cross-sectional view of the housing taken along line B-B′ of FIG. 3.

Referring to FIGS. 1 through 6, a vibration generating apparatus 100 according to an embodiment of the present invention may include a housing 200, a magnet 120, and a vibrator 140.

Here, terms with respect to directions will be defined. As viewed in FIG. 1, an axial direction refers to a vertical direction, and a radial direction refers to a direction from the center (i.e., a center line) of the housing 200 to an outer circumferential surface thereof or a direction from the outer circumferential surface of the housing 200 to the center (i.e. the center line) thereof.

Also, a circumferential direction means a direction of a rotation along the outer circumferential surface of the housing 200.

The housing 200 may include a bracket 220 having a protrusion part 222 protruding from an edge of the bracket 220 and a case 240 coupled to the bracket 220 and having an insertion hole 242 into which the protrusion part 222 is inserted when the bracket 220 and the case 240 are coupled to each other.

Meanwhile, a detailed description of the housing 200 will be described later.

The magnet 120 may be installed in an internal space formed by the bracket 220 and the case 240. That is, the magnet 120 may be fixed to the case 240 and have a cylindrical shape.

Meanwhile, although a case in which the magnet 120 is installed in the case 240 is exemplarily described in the present embodiment, the present invention is not limited thereto. That is, the magnet 120 may be installed in the bracket 220.

Also, a yoke plate 124 for reducing a leakage of magnetic force (a magnetism loss) may be installed in the magnet 120. That is, the yoke plate 124 may be installed in a top surface of the magnet 120 in order to inhibit a reduction of a driving force due to the leakage of the magnetic force.

The yoke plate 124 is installed in the magnet 120 in the present embodiment; however, the yoke plate 124 may not be provided.

The vibrator 140 may interact with the magnet 120 electromagnetically and vibrate. To this end, the vibrator 140 may include a coil 142, an installation member 144, a weight body 146, and an elastic member 148.

The coil 142 may be mounted in the installation member 144 so that the coil 142 may be disposed to face an outer circumferential surface of the magnet 120, and may have a cylindrical shape. That is, the coil 142 may be fixed to an inner circumferential surface of the installation member 144 so that an inner circumferential surface of the coil 142 and the outer circumferential surface of the magnet 120 may be disposed to face each other.

Accordingly, in a case in which power is supplied to the coil 142, driving force is generated to vibrate the vibrator 140 in the vertical direction according to the electromagnetic interaction between the coil 142 and the magnet 140.

The installation member 144 may have an “L” shaped cross-section, and have the coil 142 installed in the inner circumferential surface thereof and the weight body 146 installed in an outer circumferential surface thereof.

The installation member 144 may include a bending part 144a in order to more stably support the weight body 146. That is, the weight body 146 may be fixed to the installation member 144 while being supported by the bending part 144a.

Also, the weight body 146 may be formed of a material having a high specific gravity. For example, the weight body 146 may be formed of tungsten and iron. That is, the weight body 146 maybe formed of the material having the high specific gravity to adjust a resonance frequency and increase an amount of vibrations by increasing the mass of the vibrator 140 while maintaining the same volume.

The weight body 146 may have a hollow ring shape in such a manner that the coil 142, the magnet 120, and the like may be disposed in the weight body 146. Meanwhile, a flexible circuit board 146a for supplying power to the coil 142 from an external power source may be installed in the weight body 146.

One end of the elastic member 148 may be installed in the housing 200 and the other end thereof may be installed to contact the coil 142 and the installation member 144. The elastic member 148 may be formed as a plate spring.

That is, an outside ring part 148a of the elastic member 148 may be bonded to the case 240 of the housing 200 and an inside ring part 148b thereof may be bonded to the coil 142 and the installation member 144.

The other end of the elastic member 148 is installed to be bonded to the coil 142 and the installation member 144 in the present embodiment; however, the elastic member 148 may be installed to be bonded to at least one of the coil 142, the installation member 144, and the weight body 146. For example, the other end of the elastic member 148 may be bonded to only the weight body 146 or may be bonded to the weight body 146 and the installation member 144.

When driving force is generated according to the electromagnetic interaction between the magnet 120 and the coil 142, the elastic member 148 may serve to provide elastic force in order to vibrate the vibrator 140 in the vertical direction.

However, the present invention is not limited to a case in which the elastic member 148 is formed as a plate spring. The elastic member 148 may be formed as a coil spring, and may employ any construction capable of providing elastic force.

Hereinafter, the housing 200 included in the vibration generating apparatus 100 according to the embodiment of the present invention, i.e., the housing 200 for a vibration generating apparatus according to the embodiment of the present invention, will now be described in more detail with reference to the drawings.

As described above, the housing 200 may include, as an example, the bracket 220 including the protrusion part 222 protruding from the edge of the bracket 220 and the case 240 coupled to the bracket 220 and having the insertion hole 242 into which the protrusion part 222 is inserted when the bracket 220 and the case 240 are coupled to each other.

First, the bracket 220 may have a circular shape.

The bracket 220 may include a support part 224 for supporting a circuit board connected to an external power source.

Meanwhile, the bracket 220 may include a step part 226 in the edge of the bracket 220 supported by a seating surface of the case 240 when the bracket 220 and the case 240 are coupled to each other. The protrusion part 222 may extend from the step part 226 in the radial direction.

An inclination surface 222a may be formed in a lower portion of the protrusion part 222 so that the protrusion part 222 may be easily inserted into the insertion holes 242 formed in the case 240. Also, when the protrusion part 222 is inserted into the insertion holes 242, the protrusion part 222 may have a length allowing the protrusion part 222 not to protrude from the outer circumferential surface of the case 240. This will later be described in greater detail.

The case 240 has a cylindrical shape of which one side is opened and has an internal space. The bracket 220 is coupled to the case 240 such that the opened side of the case 240 is closed.

Meanwhile, the case 240 may include an extension part 244 thinner than a lower portion thereof such that the edge of the bracket 220, i.e. the step part 226, maybe seated when the bracket 220 and the case 240 are coupled to each other.

As such, since the extension part 244 thinner than the lower portion of the case 240 is formed, a seating surface 246 in which the step part 226 is seated and supported may be formed in the case 240. When the bracket 220 is coupled to the case 240, a bottom surface of the step part 226 of the bracket 220 is supported by the seating surface 246 of the case 240.

Also, the insertion hole 242 may be formed below the extension part 244, and the plurality of insertion holes may be provided to be spaced apart from each other in the circumferential direction.

An upper portion of the extension part 244 may be bent in order to pressurize a top edge of the bracket 220, in other words, a top surface of the step part 226, when the bracket 220 and the case 240 are coupled to each other.

Accordingly, the bottom surface of the step part 226 is supported by the seating surface 246 and the top surface thereof is pressed by the extension part 224.

Therefore, the bracket 220 may be more firmly coupled to the case 240.

In addition, the protrusion part 222 extending in the radial direction from the step part 226 may also be pressed by the bent upper portion of the extension part 244 so that the bracket 220 may be more firmly coupled to the case 240.

Accordingly, even in the case that external force is applied to the bracket 220, since the protrusion part 222 is pressed by the upper portion of the extension part 244, the protrusion part 222 maybe prevented from being separated from the case 240.

Finally, a deformation of the bracket 220 due to the external force may be reduced.

More specifically, in a case in which the upper portion of the insertion hole 242 into which the protrusion part 222 is inserted is opened, in other words, in a case in which the protrusion part 222 is not pressed by the extension part 244, when external force is applied thereto, the protrusion part 222 may be deformed toward the opened side (an upper side) of the case due to the external force.

In this case, since the protrusion part 222 is not supported, the bracket 220 may be finally deformed. However, as described above, the housing 200 for the vibration generating apparatus according to the embodiment of the present invention may reduce the deformation of the bracket 220 due to a deformation of the protrusion part 222 since the protrusion part 222 is inserted into the insertion hole 242, and the upper surface of the protrusion part 222 is pressed by the extension part 244.

Also, since the upper surface of the protrusion part 222 is pressed by the extension part 244, a lower surface of the protrusion part 222 may closely contact the case 240. Accordingly, foreign objects may be further inhibited from being introduced into the inside of the housing 200 through a space formed by the lower surface of the protrusion part 222 and a surface of the case 240 facing the lower surface of the protrusion part 222.

Meanwhile, the protrusion part 222 may protrude from the edge of the bracket 220 by a distance less than a thickness of the extension part 244 in the radial direction. Accordingly, in a case in which the bracket 220 is coupled to the case 240, the protrusion part 222 may not protrude from the outer circumferential surface of the case 240.

Hereinafter, a method of assembling the housing 200 according to an embodiment of the present invention will briefly be described with reference to the drawings.

First, the bracket 220 is coupled to the case 240 in such a manner that the protrusion part 222 of the bracket 220 may be inserted into the insertion hole 242 of the case 240. At this time, the inclination surface 222a is formed in the lower portion of the protrusion part 222, thereby allowing the protrusion part 222 to be more easily inserted into the insertion hole 242.

As such, when the bracket 220 is coupled to the case 240, the step part 226 of the bracket 220 is seated on the seating surface 246 of the case 240.

Thereafter, the upper portion of the extension part 244 of the case 240 is bent (i.e., curled) toward the inside thereof in the radial direction so that the top surface of the step part 226 of the bracket 220 and the top surface of the protrusion part 222 may be pressed.

As described above, the step part 226 and the protrusion part 222 are pressed by the upper portion of the extension part 244, whereby coupling force between the bracket 220 and the case 240 may be increased.

In addition, since the top surface of the protrusion part 222 is pressed, even in the case that external force is applied thereto, the protrusion part 222 is inhibited from being deformed, thereby reducing a deformation of the bracket 220 in which the bracket 220 is wholly twisted.

Further, the lower surface of the protrusion part 222 and the facing surface of the case 220 may maintain a state of close contact, thereby inhibiting foreign objects from being introduced into the inside of the housing 200 from the outside.

Hereinafter, a housing for a vibration generating apparatus according to another embodiment of the present invention will now be described with reference to the drawings. However, the elements of the present embodiment that are the same as the elements of the previous embodiment are described above, and thus detailed descriptions thereof will be omitted.

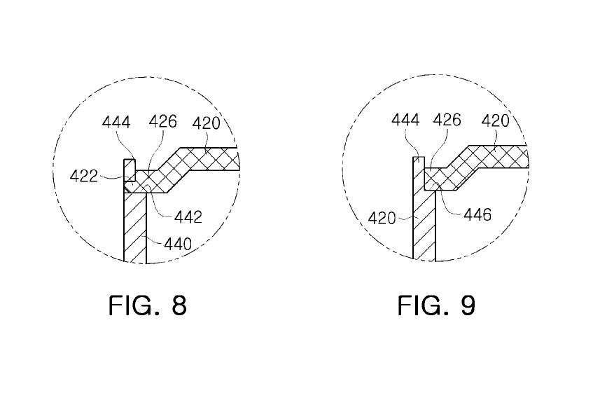

FIG. 7 is a schematic perspective view of a housing for a vibration generating apparatus according to another embodiment of the present invention. FIG. 8 is a cross-sectional view of the housing taken along line C-C′ of FIG. 7. FIG. 9 is a cross-sectional view of the housing taken along line D-D′ of FIG. 7.

Referring to FIGS. 7 through 9, a housing 400 for a vibration generating apparatus according to another embodiment of the present invention may include a bracket 420 and a case 440, as an example.

Meanwhile, the bracket 420 and the case 440 according to the present embodiment are the same as the bracket 220 and the case 240 included in the housing 200 according to the previous embodiment, except the construction that will be described below.

First, the bracket 420 may include a protrusion part 422. The protrusion part 422 may extend from a step part 426. The protrusion part 422 may be thinner than the step part 426.

In addition, a length of the protrusion part 422 in a radial direction may be smaller than a thickness of an extension part 444 so that the protrusion part 422 does not protrude outwardly from an outer circumferential surface of the case 440.

Meanwhile, the extension part 444 according to the present embodiment is not bent when the bracket 420 is coupled to the case 440. Accordingly, the extension part 444 may have a length in an axial direction allowing the step part 426 not to protrude upwardly of an upper portion thereof.

Also, an insertion hole 442 into which the protrusion part 422 is inserted may be formed below the extension part 444.

In the present embodiment, the protrusion part 422 may be coupled to the insertion hole 442 through forcible insertion, and may be coupled to the insertion hole 442 by using an adhesive agent for increasing a coupling force as a medium.

As described above, the upper portion of the extension part 444 may not be bent, thereby further simplifying an assembling process of the bracket 420 and the case 440. Accordingly, a manufacturing yield may be enhanced.

Meanwhile, since the protrusion part 422 is inserted into the insertion hole 442, a lower surface of the protrusion part 422 and a surface of the case 440 facing the lower surface of the protrusion part 422 may closely contact each other. Accordingly, even in the case that external force is applied thereto, the protrusion part 422 may be inhibited from being deformed, thereby reducing a deformation of the bracket 420 in which the bracket 420 is wholly twisted.

Further, the lower surface of the protrusion part 422 and the facing surface of the case 440 may maintain a state of close contact, thereby inhibiting foreign objects from being introduced into the inside of the housing 400 from the outside.

As set forth above, according to embodiments of the present invention, a bracket including a protrusion part and a case including an insertion hole may reduce a separation therebetween in which external force is applied thereto. In addition, the bracket is prevented from being deformed, thereby inhibiting a deformation of a housing.

While the present invention has been shown and described in connection with the embodiments, it will be apparent to those skilled in the art that modifications and variations can be made without departing from the spirit and scope of the invention as defined by the appended claims.

What is claimed is:

1. A housing for a vibration generating apparatus comprising:
a bracket including a protrusion part protruding from an edge thereof; and
a case coupled to the bracket and having an insertion hole into which the protrusion part is inserted when the case is coupled to the bracket.

2. The housing for a vibration generating apparatus of claim 1, wherein the case includes an extension part, thinner than a lower portion thereof, such that the edge of the bracket is seated when the case is coupled to the bracket.

3. The housing for a vibration generating apparatus of claim 2, wherein an upper portion of the extension part is bent to thereby press a top edge of the bracket when the case is coupled to the bracket, and
the insertion hole is formed below the extension part.

4. The housing for a vibration generating apparatus of claim 1, wherein the bracket includes a step part in the edge thereof supported by a seating surface of the case when the case is coupled to the bracket, and
the protrusion part extends from the step part.

5. The housing for a vibration generating apparatus of claim 1, wherein the protrusion part has an inclination surface formed in a lower portion thereof in order to facilitate the insertion of the protrusion part into the insertion hole.

6. The housing for a vibration generating apparatus of claim 2, wherein the protrusion part protrudes from the edge of the bracket by a distance less than a thickness of the extension part in a radial direction.

7. The housing for a vibration generating apparatus of claim 1, wherein the bracket and the case have circular cross-sections, and
the protrusion part and the insertion hole are provided in plural, the plural protrusion parts and insertion holes respectively being spaced apart from each other in a circumferential direction.

8. A vibration generating apparatus comprising:
a housing including a bracket having a protrusion part protruding from an edge thereof, and a case coupled to the bracket and having an insertion hole into which the protrusion part is inserted when the case is coupled to the bracket;
a magnet installed in an internal space formed by the bracket and the case; and
a vibrator vibrated through electromagnetic interaction with the magnet.

9. The vibration generating apparatus of claim 8, wherein the case includes an extension part thinner than a lower portion thereof, such that the edge of the bracket is seated when the case is coupled to the bracket, and
the insertion hole is formed below the extension part.

10. The vibration generating apparatus of claim 8, wherein an upper portion of the extension part is bent to thereby press a top edge of the bracket when the case is coupled to the bracket,
the bracket includes a step part in the edge thereof supported by a seating surface of the case when the case is coupled to the bracket, and
the protrusion part extends from the step part.

11. The vibration generating apparatus of claim 8, wherein the protrusion part has an inclination surface formed in a lower portion thereof in order to facilitate the insertion of the protrusion part into the insertion hole, and
the protrusion part protrudes from the edge of the bracket by a distance less than a thickness of the extension part in a radial direction.
